(19) United States
(12) Patent Application Publication
(10) Pub. No.: US 2026/0221810 A1
(43) Pub. Date: Jul. 30, 2026

(54) SHIELDING MEMBER MADE OF POLYMER MATERIAL AND WIRELESS POWER RECEPTION MODULE INCLUDING SAME

(71) Applicant: AMOSENSE CO., LTD, Cheonan-si (KR)

(72) Inventors: Kil-Jae JANG, Cheonan-si (KR); Dong-Hoon LEE, Cheonan-si (KR)

(73) Assignee: AMOSENSE CO., LTD, Cheonan-si (KR)

(21) Appl. No.: 19/143,919

(22) PCT Filed: Dec. 22, 2023
(86) PCT No.: PCT/KR2023/021409

§ 371 Date: Jun. 27, 2025

(30) Foreign Application Priority Data
Dec. 27, 2022 (KR) 10-2022-0186354
Dec. 22, 2023 (KR) 10-2023-0189328

(51) Int. Cl. H02J 50/70; H01F 27/36; H02J 50/00; H02J 50/10; H02J 50/90; H05K 9/00

(52) U.S. Cl. CPC H02J 50/70; H01F 27/366; H02J 50/005; H02J 50/10; H02J 50/90; H05K 9/0083

(57) ABSTRACT

A shielding member may include: a base part through which an arrangement hole having a predetermined area is formed at the center thereof; a ring-shaped first blocking part which is formed along the rim of the arrangement hole to protrude a certain height from the base part; and an antenna accommodation part which is defined by one surface of the first blocking part and one surface of the base part and is formed at one surface of the base part along the circumferential direction of the first blocking part, wherein each of the base part and the first blocking part is made of a polymer material including a polymer resin and platelike magnetic bodies oriented in along one direction, and the base part and the first blocking part are formed integrally with each other.

### CROSS REFERENCE TO THE RELATED APPLICATIONS

This application is the national phase entry of International Application No. PCT/KR2023/021409, filed on Dec. 22, 2023, which is based upon and claims priority to Korean Patent Applications No. 10-2022-0186354, filed on Dec. 27, 2022, and No. 10-2023-0189328, filed on Dec. 22, 2023, the entire contents of which are incorporated herein by reference.

### TECHNICAL FIELD

The present invention relates to a shielding member made of a polymer material and a wireless power reception module including the same.

### BACKGROUND

Wireless power transmission technology is convenient for users because it does not require a separate wired cable for charging. Accordingly, wireless power transmission technology is widely used as a method for charging batteries in various electronic devices.

Battery charging using this wireless power transmission requires that the wireless power transmission module and the wireless power reception module are aligned with each other to satisfy the required charging efficiency.

As part of this, the wireless power transmission module and the wireless power reception module can maintain an aligned state by using the DC magnetic field generated from the magnet by arranging a permanent magnet for alignment at the center of the antenna.

However, if a permanent magnet is arranged around the antenna, there is a problem in that the charging efficiency decreases due to the influence of the permanent magnet.

In order to solve this problem, the shielding member used for each of the wireless power transmission module and the wireless power reception module forms an accommodating groove to accommodate the antenna, thereby reducing the influence of the permanent magnet.

However, when the accommodating groove is formed in the shielding member, the part that surrounds the side of the antenna while defining the accommodating groove protrudes from a plate-shaped part by a certain height.

Accordingly, if the shielding member is made of brittle sintered ferrite, the part protruding from the plate-shaped part to a certain height while defining the accommodating groove and wrapping the side of the antenna is bound to be very vulnerable to external impact.

As a result, if the part that defines the accommodating groove and wraps the side of the antenna falls or separates due to impact during a drop test, there is a problem in that each of the wireless power transmission module and wireless power reception module to which the above-described shielding member is applied will not pass the quality certification.

### SUMMARY

### Technical Problem

The present invention has been devised in consideration of the above points, and an object of the present invention is to provide a shielding member that has a higher permeability than a shielding member using a conventional polymer material, and can improve the problem of a protruding part being damaged by impact even if the shielding member includes the protruding part, and a wireless power reception module including the same.

Technical Solution

In order to achieve the above object, the present invention provides a shielding member made of a polymer material, including a base part through which an arrangement hole having a predetermined area is formed at a center thereof; a ring-shaped first blocking part that is formed along a rim of the arrangement hole to protrude a certain height from the base part; and an antenna accommodation part that is defined by one surface of the first blocking part and one surface of the base part and is formed at one surface of the base part along a circumferential direction of the first blocking part, wherein each of the base part and the first blocking part is made of a polymer material including a polymer resin and plate-shaped magnetic bodies mixed in the polymer resin to have an orientation along one direction, and wherein the base part and the first blocking part are formed integrally with each other.

In addition, the plate-shaped magnetic bodies may be arranged so as to face in a direction parallel to a length or width direction of the shielding member.

In addition, the antenna accommodation part may be formed as a sloped surface with a bottom surface inclined at a certain angle.

In addition, the shielding member further may include a ring-shaped second blocking part that is formed by protruding from the base part to a certain height in the same direction as the first blocking part along a rim of the base part, wherein the second blocking part is made of a polymer material including a plate-shaped magnetic body mixed with the polymer resin so as to have an orientation along one direction, and wherein the base part, the first blocking part and the second blocking part are integrally formed.

In addition, a width of the first blocking part may be formed to be equal to or wider than a width of the second blocking part.

In addition, a protrusion height of the first blocking part protruding from one surface of the base part may be formed to have a size that is greater than or equal to a protrusion height of the second blocking part protruding from one surface of the base part.

In addition, the arrangement hole may be a space for accommodating a permanent magnet for alignment.

In addition, the shielding member may include at least one first region and second region having a lower density than the first region.

In addition, the second region may have a density of 2.5 to 3.5 g/cm³ and a distance between plate-shaped magnetic bodies of 3 to 50 μm.

In addition, the plate-shaped magnetic body may have an average particle diameter of 5 to 200 μm and a ratio of thickness to maximum length of 1:45 or more.

In addition, the polymer resin and the plate-shaped magnetic body may be included in a weight ratio of 1:1.4 to 20.

In addition, the shielding member may have a permeability of 30 to 500 in a 100 KHz frequency band, and a saturation magnetic flux density of 0.3 to 1.6 T.

Meanwhile, the present invention provides a wireless power reception module, including a wireless power reception antenna for receiving wireless power; a permanent magnet for alignment arranged at a center of the wireless power reception antenna; and a shielding member for shielding a magnetic field, wherein the shielding member is the above-described shielding member made of a polymer material, wherein the wireless power reception antenna is placed in the antenna accommodation part, and wherein the permanent magnet for alignment is placed in the arrangement hole.

### Advantageous Effects

According to the present invention, it is possible to improve the performance as a shielding sheet while solving the quality certification problem by improving the problem of a protruding part being damaged by impact while having a higher permeability than before.

### BRIEF DESCRIPTION OF DRAWINGS

FIG. 1 is a drawing showing a shielding member according to an embodiment of the present invention,

FIG. 2 is a cross-sectional view taken along the line A-A of FIG. 1,

FIG. 3 is a drawing showing a modified example of FIG. 2,

FIG. 4 is a drawing showing a shielding member according to another embodiment of the present invention,

FIG. 5 is a cross-sectional view taken along the line B-B of FIG. 4,

FIG. 6 is a drawing showing a modified example of FIG. 5,

FIG. 7 is a drawing showing a wireless power reception module to which the shielding member of FIG. 2 is applied,

FIG. 8 is a drawing showing a wireless power reception module to which the shielding member of FIG. 3 is applied,

FIG. 9 is a drawing showing a wireless power reception module to which the shielding member of FIG. 5 is applied,

FIG. 10 is a drawing showing a wireless power reception module to which the shielding member of FIG. 6 is applied, and

FIG. 11 is a drawing showing the arrangement relationship between the wireless power reception module and the wireless power transmission module of FIG. 10.

### DETAILED DESCRIPTION OF THE EMBODIMENTS

Hereinafter, with reference to the attached drawings, embodiments of the present invention will be described in detail so that those skilled in the art can easily practice the present invention. The present invention may be implemented in various different forms and is not limited to the embodiments described herein. In order to clearly describe the present invention in the drawings, parts that are not related to the description are omitted, and the same reference numerals are assigned to the same or similar components throughout the specification.

The words and terms used in the present specification and claims are not to be limited to their common or dictionary meanings, but should be interpreted as meanings and concepts that conform to the technical idea of the present invention according to the principle that the inventor can define terms and concepts in order to explain his or her invention in the best way.

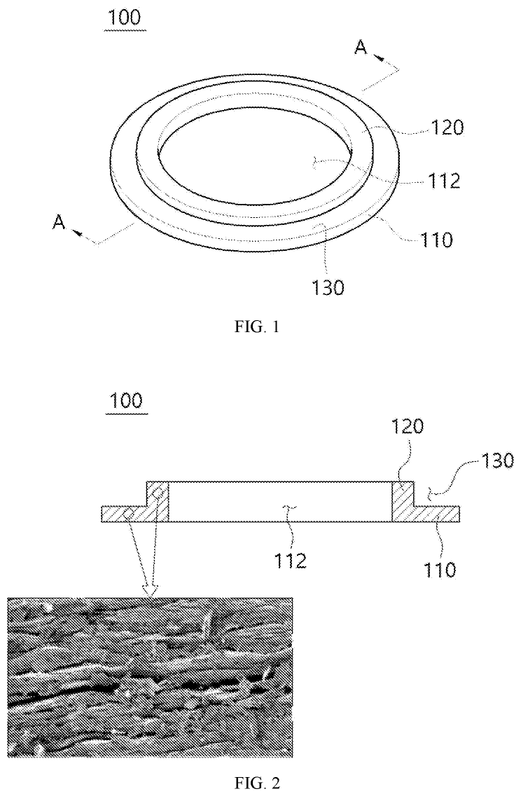

In addition, the upper surface used in the present specification and claims may mean a surface viewed from above based on FIG. 1, the lower surface may mean a surface viewed from below based on FIG. 1, and the side and lateral surface may mean a surface viewed from the left or right based on FIG. 2. Moreover, the thickness direction and height direction used in the present specification and claims may mean a direction parallel to the direction from the top surface to the bottom surface or from the bottom surface to the top surface based on FIG. 1, and the width direction or length direction may mean a direction parallel to the direction from the left to the right or from the right to the left based on FIG. 2.

The shielding member 100, 100′, 200, 200′ made of a polymer material according to an embodiment of the present invention (hereinafter, referred to as the ‘shielding member’) may prevent damage due to external impact by improving the brittleness of the material itself of sintered ferrite compared to a conventional shielding member made of sintered ferrite such as Mn-Zn ferrite or Ni-Zn ferrite.

In addition, the shielding member 100, 100′, 200, 200′ according to an embodiment of the present invention may be implemented to have a greater permeability compared to a conventional shielding member made of a polymer material, thereby increasing shielding performance.

Moreover, the shielding member 100, 100′, 200, 200′ according to an embodiment of the present invention may prevent the performance deterioration of the antenna by the DC magnetic field generated from the permanent magnet for alignment 320 even when the permanent magnet for alignment 320 is placed in the center.

To this end, the shielding member 100, 100′, 200, 200′ according to an embodiment of the present invention may be made of a polymer material, and may be formed to have a predetermined shape from a polymer sheet. Alternatively, it may be formed to have a predetermined shape through a composition including a polymer resin and a plate-shaped magnetic body, which will be described below.

That is, the shielding member 100, 100′, 200, 200′ according to an embodiment of the present invention may be provided such that the first blocking part 120 or the second blocking part 140 protrudes in a ring shape from one surface of the base part 110 by pressing a polymer sheet having a predetermined area. Alternatively, the shielding member may be provided such that the first blocking part 120 or the second blocking part 140 protrudes in a ring shape from one surface of the base part 110 by pressing a composition including a polymer resin and a plate-shaped magnetic body, which will be described below.

Accordingly, in the shielding member 100, 100′, 200, 200′ according to an embodiment of the present invention, the base part 110 and the first blocking part 120, the base part 110 and the first blocking part 120 and the second blocking part 140 may be formed integrally.

Herein, the polymer resin may be formed of epoxy resin, acrylic resin, cycloolefin resin, PP, PVC and the like, and the plate-shaped magnetic body may be formed of a material having magnetism. For example, the magnetic body may be FeSiAl, but is not limited thereto, and all known magnetic materials used as polymer sheets may be used.

That is, the polymer sheet used to form the shielding member 100, 100′, 200, 200′ according to an embodiment of the present invention may be a mixture of FeSiAl, a solvent and the polymer resin.

In this case, the shielding member 100, 100′, 200, 200′ according to an embodiment of the present invention may be manufactured from the above-described polymer sheet or from the composition, and the plate-shaped magnetic body mixed in the polymer resin may be mixed in the polymer resin so as to have an orientation along one direction.

That is, the plate-shaped magnetic body may be arranged so as to be oriented in a direction parallel to the length direction of the polymer sheet having a predetermined area, and the shielding member 100, 100′, 200, 200′ according to an embodiment of the present invention manufactured using the polymer sheet may be in a state in which the plate-shaped magnetic bodies face a direction parallel to the length direction or the width direction of the shielding member. Alternatively, the plate-shaped magnetic bodies may be arranged so as to face a direction parallel to the length direction or the width direction of the shielding member 100, 100′, 200, 200′ according to an embodiment of the present invention by being press-molded while being mixed in the composition.

In this case, the shielding member 100, 100′, 200, 200′ according to an embodiment of the present invention may be formed by applying a mixture including the polymer resin and the plate-shaped magnetic body to one surface of a carrier film to have a predetermined thickness, and then pressing the mixture applied to one surface of the carrier film to have a thinner thickness and a wider area, and then pressing the mixture to have a predetermined shape. Alternatively, the composition may be formed to have a predetermined shape by pressing the composition directly.

Through this, the plate-shaped magnetic body included in the mixture may be oriented in a direction parallel to the length direction of the polymer sheet in the process of pressing the mixture to have a predetermined thickness and expanding the polymer sheet to have a thinner thickness and a wider area than the mixture applied to the carrier film.

Accordingly, the shielding member 100, 100′, 200, 200′ according to an embodiment of the present invention is formed to have a predetermined shape through press processing in a state where the plate-shaped magnetic body is arranged to have an orientation along one direction such that the plate-shaped magnetic body constituting the shielding member may be arranged to have an orientation along one direction as shown in the enlarged views of FIGS. 2, 3, 5 and 6.

As a result, the shielding member 100, 100′, 200, 200′ according to an embodiment of the present invention may be implemented to have a higher permeability compared to the conventional shielding member made of a polymer material while preventing damage to the first blocking part 120 and the second blocking part 140 due to external force by improving the strength.

The shielding member 100, 100′, 200, 200′ according to an embodiment of the present invention may include a base part 110, a first blocking part 120 and an antenna accommodation part 130 as shown in FIGS. 1 to 6.

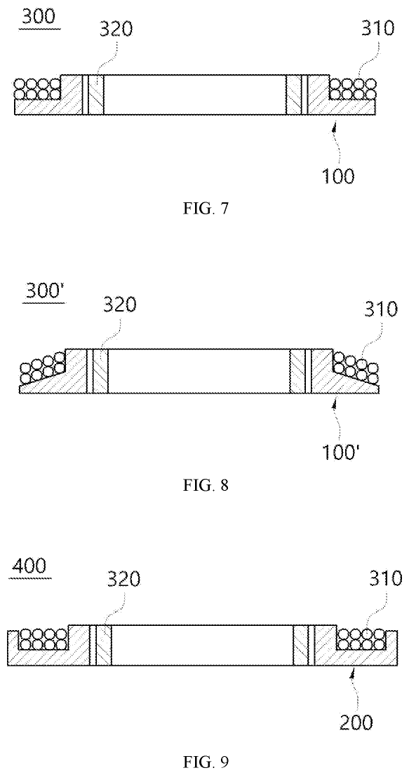

The base part 110 may shield a magnetic field generated from a wireless power transmission antenna, such as a wireless power transmission antenna (see 510 of FIG. 11) or a wireless power reception antenna (see 310 of FIG. 7), and may increase the concentration of the magnetic field in a desired direction, thereby improving the performance of the wireless power transmission antenna operating in a predetermined frequency band.

Herein, the wireless power transmission antenna may be a flat coil in which a conductive member is wound multiple times along one direction, and the conductive member may be a known Litz wire.

The base part 110 as described above may be made of a polymer material, and the plate-shaped magnetic body may be oriented in a direction parallel to the bottom surface or top surface of the base part 110.

In this case, the base part 110 may include an arrangement hole 112 for arranging a permanent magnet 320 for alignment.

Herein, the permanent magnet for alignment 320 may be provided in a ring shape when the shielding member 100, 100′, 200, 200′ according to an embodiment of the present invention is applied to the wireless power reception module 300, 300′, 400, 400′), but is not limited thereto, and it may be provided in a circular plate or cylindrical shape.

For example, the arrangement hole 112 may be formed to penetrate the base part 110 with a predetermined area.

Accordingly, the permanent magnet for alignment 320 may be inserted into the arrangement hole 112 side, and the permanent magnet for alignment 320 may align the other module to the correct position through interaction with the permanent magnet for alignment (see 520 of FIG. 11) provided in the corresponding other module during wireless power transmission.

The first blocking part 120 may be formed by protruding from the base part 110 along a rim of the arrangement hole 112 to a certain height.

For example, the first blocking part 120 may be provided in a ring shape that is formed by protruding from one surface of the base part 110 so as to surround the circumference of the arrangement hole 112.

In this way, the first blocking part 120 may be formed of a polymer material as described above, and the plate-shaped magnetic body may be oriented in a direction parallel to the bottom surface or top surface of the first blocking part 120.

Through this, the first blocking part 120 may serve as a blocking wall that blocks a direct current magnetic field generated from a permanent magnet 320 for alignment inserted into the arrangement hole 112.

That is, the shielding member 100, 100′, 200, 200′ according to an embodiment of the present invention may shield a magnetic field generated from the permanent magnet for alignment 320 through the first blocking part 120 even if the permanent magnet for alignment 320 is inserted into the arrangement hole 112.

As a result, the shielding member 100, 100′, 200, 200′ according to an embodiment of the present invention may prevent the performance deterioration of the wireless power transmission antenna by the DC magnetic field generated from the permanent magnet for alignment 320 even if the permanent magnet for alignment 320 is inserted into the arrangement hole 112.

In this case, the first blocking part 120 may be formed integrally with the base part 110.

That is, as described above, the first blocking part 120 and the base part 110 may be integrally formed through press processing from a plate-shaped polymer sheet having a predetermined area through press processing.

Accordingly, the shielding member 100, 100′, 200, 200′ according to an embodiment of the present invention may improve brittleness since the sintering process is omitted compared to the conventional shielding member made of sintered ferrite, and it may fundamentally prevent problems of deformation such as distortion that may occur during the sintering process.

Moreover, the shielding member 100, 100′, 200, 200′ according to an embodiment of the present invention may improve strength by arranging the plate-shaped magnetic body to be parallel to the bottom surface or the top surface of the base part 110 or the top surface of the first blocking part 120.

Accordingly, the shielding member 100, 100′, 200, 200′ according to an embodiment of the present invention may solve the quality certification problem by improving the problem of the first blocking member 120 protruding from the base 110 from being damaged by impact even though it includes the first blocking member 120 protruding from the base 110 at a certain height to shield the DC magnetic field generated from the permanent magnet for alignment 320.

Moreover, the shielding member 100, 100′, 200, 200′ according to an embodiment of the present invention may be implemented to have a higher magnetic permeability compared to a conventional shielding member made of a polymer material by arranging the plate-shaped magnetic body to be parallel to the bottom surface or the top surface of the base 110 or the top surface of the first blocking member 120.

The antenna accommodation part 130 may be formed on one surface of the base 110.

That is, as described above, when the first blocking part 120 is formed by protruding a certain height from one surface of the base part 110, the antenna accommodation part 130 may be defined by one surface of the first blocking part 120 and one surface of the base part 110, and may be formed on one surface of the base part 110 along a circumferential direction of the first blocking part 120 formed in a ring shape.

Specifically, the antenna accommodation part 130 may be defined by the upper surface of the base part 110 and the side surface of the first blocking part 120 based on FIG. 2, and the antenna accommodation part 130 may be formed on the upper surface of the base part 110 along the outer circumferential surface of the first blocking part 120.

Such an antenna accommodation part 130 may be a space where a wireless power transmission antenna is arranged, and may accommodate the thickness of the wireless power transmission antenna.

For example, as shown in FIGS. 7 to 10, when the wireless power transmission antenna is provided as a flat coil, the flat coil may have a coil body arranged in the antenna accommodation part 130, and the thickness of the flat coil arranged in the antenna accommodation part 130 may be accommodated by the protrusion height h1 of the first blocking part.

Herein, the protrusion height h1 of the first blocking part, which protrudes from one surface of the base part 110 by a certain height, may be equal to or lower than the thickness of the flat coil.

Accordingly, when the permanent magnet for alignment 320 is placed in the arrangement hole 112 and the flat coil is placed in the antenna accommodation part 130, the DC magnetic field generated from the permanent magnet for alignment 320 may be blocked by the first blocking part 120, thereby preventing the performance deterioration of the flat coil by the DC magnetic field.

Meanwhile, the shielding member 200, 200′ according to an embodiment of the present invention may further include a first blocking part 120 that is formed by protruding a certain height from the base part 110 along a rim of the arrangement hole 112 as shown in FIGS. 4 to 6, and a second blocking part 140 in a ring shape that is formed by protruding a certain height from one surface of the base part 110 in the same direction as the first blocking part 120 along a rim of the base part 110.

In this case, the antenna accommodation part 130 formed on one surface of the base part 110 may be formed in the shape of a groove with an open top.

That is, as described above, when the first blocking part 120 and the second blocking part 140 are formed to protrude a certain height from one surface of the base part 110, the antenna accommodation part 130 may be defined by one surface of the first blocking part 120, one surface of the base part 110 and one surface of the second blocking part 140, and may be formed on one surface of the base part 110 so as to be positioned between the first blocking part 120 and the second blocking part 140 formed in a ring shape.

Specifically, the antenna accommodation part 130 may be defined by the upper surface of the base part 110, the outer surface of the first blocking part 120 and the inner surface of the second blocking part 140 based on FIG. 5, and the antenna accommodation part 130 may be formed on the upper surface of the base part 110 along the outer peripheral surface of the first blocking part 120 and the inner peripheral surface of the second blocking part 140.

Accordingly, when a flat coil is arranged in the antenna accommodation part 130, the inner rim of the flat coil may be wrapped through the outer peripheral surface of the first blocking part 120, and the outer rim of the flat coil may be wrapped through the inner peripheral surface of the second blocking part 140.

In this case, the second blocking part 140 may be made of a polymer material as described above, and the plate-shaped magnetic body may be oriented in a direction parallel to the upper surface of the second blocking part 140.

Through this, the second blocking part 140 may shield a magnetic field, similarly to the base part 110 and the first blocking part 120.

In addition, the second blocking part 140 may be formed integrally with the base part 110.

That is, as described above, the first blocking part 120, the second blocking part 140 and the base part 110 may be formed integrally through press processing from a plate-shaped polymer sheet having a predetermined area through press processing.

Accordingly, the shielding member 100, 100′, 200, 200′ according to an embodiment of the present invention may improve brittleness since the sintering process is omitted compared to a conventional shielding member made of sintered ferrite, and it may fundamentally prevent problems of deformation such as distortion that may occur during the sintering process.

Moreover, the shielding member 100, 100′, 200, 200′ according to an embodiment of the present invention may improve strength by arranging the plate-shaped magnetic body to be parallel to the bottom surface or the top surface of the base part 110 or the top surface of the first blocking part 120 and the second blocking part 140.

As a result, even though the shielding member 100, 100′, 200, 200′ according to an embodiment of the present invention includes the first blocking part 120 and the second blocking part 140 protruding from the base part 110 by a certain height in order to shield the DC magnetic field generated from the permanent magnet for alignment 320, the problem of the first blocking part 120 and the second blocking part 140 protruding from the base part 110 being damaged by impact may be improved, thereby solving the quality certification problem.

Moreover, the shielding member 100, 100′, 200, 200′ according to an embodiment of the present invention may be implemented to have a higher permeability compared to a conventional shielding member made of a polymer material by arranging a plate-shaped magnetic body to be parallel to the bottom surface or upper surface of the base part 110 or the upper surfaces of the first blocking part 120 and the second blocking part 140.

In this case, each of the first blocking part 120 and the second blocking part 140 may be formed in a ring shape having a closed loop shape as described above, and the first blocking part 120 may be provided to have a relatively smaller size than the second blocking part 140.

Meanwhile, the shielding member 100, 100′, 200, 200′ according to an embodiment of the present invention may include at least one first region and second region having a lower density than the first region. As described above, since it includes a second region having a lower density than the first region, it may be more advantageous in terms of durability against external force.

In this case, the first region may have a density of 3.5 to 4.5 g/cm³, and the distance between the plate-shaped magnetic bodies may be 3 μm or less, and preferably, the first region may have a density of 3.6 to 4.4 g/cm³, and the distance between the plate-shaped magnetic bodies may be less than 3 μm, and the second region may have a density of 2.5 to 3.5 g/cm³, and the distance between the plate-shaped magnetic bodies may be 3 to 50 μm. In addition, preferably, the second region may have a density of 2.6 to 3.4 g/cm³, and the distance between the plate-shaped magnetic bodies may be 5 to 45 μm. If the density of the first region is less than 3.5 g/cm³ or the distance between the plate-shaped magnetic bodies is more than 3 μm, the permeability may deteriorate, which may result in a decrease in the inductance Ls, and if the density is more than 4.5 g/cm³, the flexibility may deteriorate, which may result in damage by a weak impact. In addition, if the density of the second region is less than 2.5 g/cm³ or the distance between the plate-shaped magnetic bodies is more than 50 μm, the formability may deteriorate, which may result in a decrease in the magnetic properties or durability, and if the density is more than 3.5 g/cm³ or the distance between the plate-shaped magnetic bodies is less than 3 μm, the magnetic body may be damaged by a weak impact.

In addition, the plate-shaped magnetic body may have an average particle diameter of 5 to 200 μm, and preferably an average particle diameter of 20 to 150 μm. If the average particle diameter of the plate-shaped magnetic body is less than 5 μm, the magnetic properties may deteriorate, and if it is more than 200 μm, the magnetic field shielding performance and/or durability against external force may deteriorate.

In addition, the plate-shaped magnetic body may have a ratio of thickness to maximum length of 1:45 or more, and preferably, the ratio of thickness to maximum length of may be 1:50 or more. If the ratio of thickness to maximum length of of the plate-shaped magnetic body is less than 1:45, the permeability may deteriorate, and thus the inductance Ls may decrease.

Meanwhile, the polymer resin and the plate-shaped magnetic body may be included in a weight ratio of 1:1.4 to 20, and preferably, they may be included in a weight ratio of 1:1.5 to 19. If the weight ratio of the polymer resin and the plate-shaped magnetic body is less than 1:1.4, the magnetic properties, antenna properties and magnetic field shielding performance may deteriorate, and if the weight ratio is more than 1:20, the formability and/or durability against external force may deteriorate.

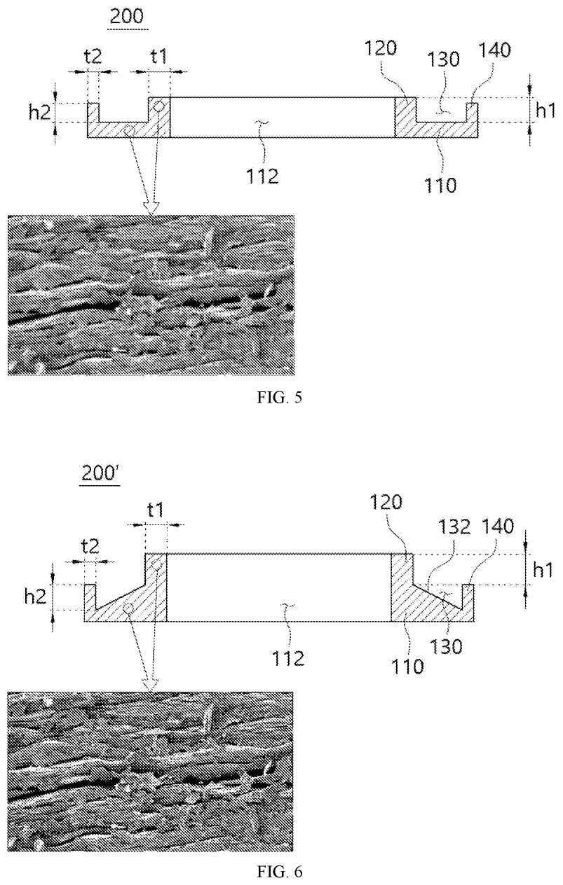

In addition, as shown in FIGS. 5 and 6, the width t1 of the first blocking part may be provided to have a width that is equal to or wider than the width t2 of the second blocking part, and the protrusion height h1 of the first blocking part protruding from one surface of the base part 110 may be formed to have a size that is equal to or larger than the protrusion height h2 of the second blocking part protruding from one surface of the base part 110.

Meanwhile, in the shielding member 100′, 200′ according to an embodiment of the present invention, a bottom surface 132 of the antenna accommodation part may be formed as a horizontal plane, but may be formed as an inclined plane inclined at a certain angle.

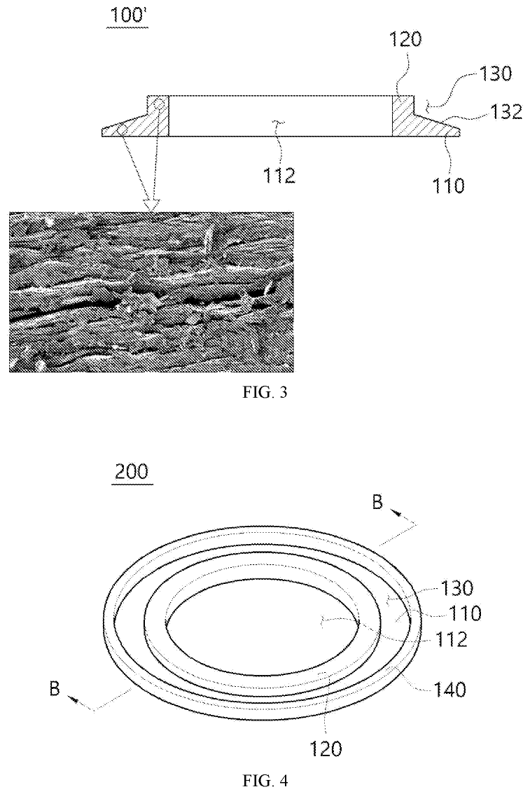

For example, as shown in FIGS. 3 and 6, the bottom surface 132 of the antenna accommodation part 130 may be formed to be inclined such that the thickness of the base part 110 becomes thinner as it goes from the first blocking part 120 to the second blocking part 140.

Through this, when the shielding member 100′, 200′ according to an embodiment of the present invention is implemented as a wireless power transmission module, the wireless power transmission antenna arranged along the inclined surface of the antenna accommodation part 130 may be arranged such that the central part has a convex shape toward one side.

Accordingly, the wireless power transmission antenna may further increase the concentration of the magnetic field by changing the shape of the central part to be convex, thereby increasing the wireless power transmission efficiency.

Meanwhile, the shielding member 100, 100′, 200, 200′ according to an embodiment of the present invention may have a permeability of 30 to 500 in a 100 KHz frequency band and a saturation magnetic flux density of 0.3 to 1.6 T (Tesla).

Meanwhile, the shielding member 100, 100′, 200, 200′ according to an embodiment of the present invention may be implemented as a wireless power transmission module.

For example, the shielding member 100, 100′, 200, 200′ according to an embodiment of the present invention may be implemented as a wireless power reception module 300, 300′, 400, 400′ as illustrated in FIGS. 7 to 10, and the wireless power reception module 300, 300′, 400, 400′ may be applied to a smartwatch.

That is, the wireless power reception module 300, 300′, 400, 400′ may include a wireless power reception antenna 310 for receiving wireless power, a permanent magnet 320 for alignment arranged in the center of the wireless power reception antenna 310 and a shielding member for shielding a magnetic field, and the shielding member may be the shielding member 100, 100′, 200, 200′ described above.

In this case, the wireless power reception antenna 310 may be a flat coil placed in the antenna accommodation part 130, and the permanent magnet for alignment 320 may be provided in a ring shape and placed in the arrangement hole 112.

Herein, the flat coil may be formed by forming a coil body by winding a conductive member having a predetermined length multiple times in a clockwise or counterclockwise direction, and the coil body may include a hollow part formed in a central part with a predetermined area, and the coil body may be formed in a single layer or multiple layers.

In addition, the conductive member forming the coil body of the flat coil may be composed of a plurality of wires having a predetermined wire diameter, the surfaces of the plurality of wires may be insulated with an insulating coating material, and the plurality of wires may be twisted with each other along the length direction or arranged in a parallel manner along one direction.

Moreover, the wireless power reception module 300, 300′, 400, 400′ may receive wireless power transmitted from a wireless power transmission module equipped in a wearable wireless charger such as a smartwatch, as shown in FIG. 11.

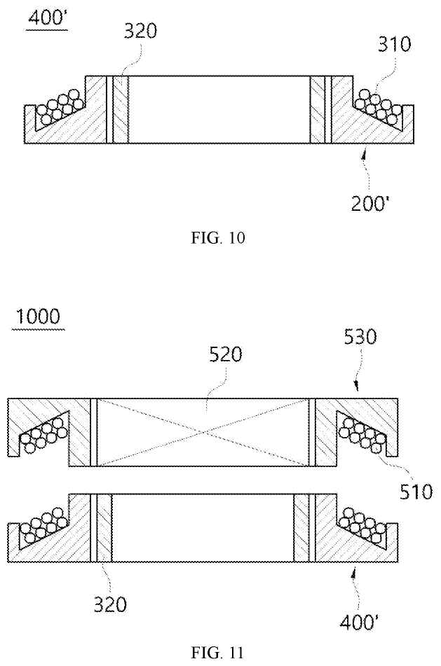

In this case, when the antenna accommodation part 130 in the shielding member 100′, 200′ includes an inclined surface, the flat coil may be formed to have a shape in which the central part is convex upward based on FIG. 8 and FIG. 10.

In this case, the wireless power transmission module may include a wireless power transmission antenna 510 equipped with a flat coil, a permanent magnet 520 for alignment arranged in the center of the wireless power transmission antenna 510 and a shielding member 530 for shielding a magnetic field, and the wireless power transmission antenna 510 may be equipped to have a central part having a convex shape downward based on FIG. 11 so as to face the wireless power reception antenna 310 at a constant interval.

Herein, the wireless power transmission antenna 510 may be a flat coil in which a conductive member is wound multiple times in one direction, and the flat coil may be formed by forming a coil body by winding a conductive member having a predetermined length multiple times in a clockwise or counterclockwise direction. Moreover, the coil body may include a hollow part formed in a central part with a predetermined area, and the coil body may be formed in a single layer or multiple layers.

In addition, the conductive member forming the coil body of the flat coil may be composed of a plurality of wires having a predetermined wire diameter, the surfaces of the plurality of wires may be insulated with an insulating coating material, and the plurality of wires may be twisted with each other along the length direction or arranged in a parallel manner along one direction.

Additionally, the shielding member 530 may be applied to the shielding member 100, 100′, 200, 200′ described above.

Accordingly, the wireless power transmitted from the wireless power transmission antenna 510 may be smoothly transmitted to the wireless power reception antenna 310 disposed on the inclined surface.

Meanwhile, although the shielding member 100, 100′, 200, 200′ according to an embodiment of the present invention is described as being applied to the wireless power reception module 300, 300′, 400, 400′, if the wireless power reception antenna 310 is replaced with a wireless power transmission antenna, the wireless power reception module 300, 300′, 400, 400′ described above may be implemented as a wireless power transmission module built into a wireless charger.

Additionally, although the wireless power reception antenna 310 disposed in the antenna accommodation part 130 is described as being provided as a flat coil in the above description, it is not limited thereto, and it may be provided as an antenna pattern formed in a pattern on a circuit board.

Although one embodiment of the present invention has been described above, the spirit of the present invention is not limited to the embodiments presented in the present specification, and those skilled in the art who understand the idea of the present invention will be able to easily suggest other embodiments by modifying, changing, deleting, or adding components within the scope of the same idea, but this will also be considered to fall within the spirit of the present invention.

What is claimed is:

1. A shielding member made of a polymer material, comprising:
a base part, wherein an arrangement hole having a predetermined area is formed at a center of the base part;
a first blocking part, wherein the first blocking part is ring-shaped and formed along a rim of the arrangement hole to protrude a first predetermined height from the base part; and
an antenna accommodation part, wherein the antenna accommodation part is defined by one surface of the first blocking part and one surface of the base part and is formed at one surface of the base part along a circumferential direction of the first blocking part;
wherein each of the base part and the first blocking part is made of a the polymer material comprising a polymer resin and plate-shaped magnetic bodies mixed in the polymer resin to have an orientation along one direction, and
wherein the base part and the first blocking part are formed integrally with each other.

2. The shielding member of claim 1, wherein the plate-shaped magnetic bodies are arranged to face in a direction parallel to a length or width direction of the shielding member.

3. The shielding member of claim 1, wherein the antenna accommodation part is formed as a sloped surface with a bottom surface inclined at a certain predetermined angle.

4. The shielding member of claim 1, further comprising:
a second blocking part, wherein the second blocking part is ring-shaped and formed by protruding from the base part to a second predetermined height in same direction as the first blocking part along a rim of the base part;
wherein the second blocking part is made of the polymer material comprising a plate-shaped magnetic body mixed with the polymer resin so as to have an orientation along one direction, and
wherein the base part, the first blocking part and the second blocking part are integrally formed.

5. The shielding member of claim 4, wherein a width of the first blocking part is formed to be equal to or wider than a width of the second blocking part.

6. The shielding member of claim 4, wherein a size of a protrusion height of the first blocking part protruding from one surface of the base part is greater than or equal to a protrusion height of the second blocking part protruding from one surface of the base part.

7. The shielding member of claim 1, wherein the arrangement hole is a space for accommodating a permanent magnet for alignment.

8. The shielding member of claim 1, wherein the shielding member comprises at least one first region and second region having a lower density than the first region.

9. The shielding member of claim 8, wherein the second region has a density of 2.5 g/cm³ to 3.5 g/cm³ and a distance between the plate-shaped magnetic bodies of 3 μm to 50 μm.

10. The shielding member of claim 1, wherein each of the plate-shaped magnetic bodies has an average particle diameter of 5 μm to 200 μm and a ratio of thickness to maximum length of 1:45 or more.

11. The shielding member of claim 1, wherein the polymer resin and the plate-shaped magnetic bodies are comprised in a weight ratio of 1:1.4 to 20.

12. The shielding member of claim 1, wherein the shielding member has a permeability of 30 to 500 in a 100 KHz frequency band, and wherein the shielding member has a saturation magnetic flux density of 0.3 to 1.6 T.

13. A wireless power reception module, comprising:
a wireless power reception antenna for receiving wireless power;
a permanent magnet for alignment arranged at a center of the wireless power reception antenna; and
the shielding member of claim 1 for shielding a magnetic field;
wherein the wireless power reception antenna is placed in the antenna accommodation part, and
wherein the permanent magnet for alignment is placed in the arrangement hole.
